(19) United States
(12) Patent Application Publication
(10) Pub. No.: US 2026/0329642 A1
(43) Pub. Date: Oct. 22, 2026

(54) ALLOCATING MEMORY GROUPS FOR ERROR AVOIDANCE USING PRIORITY INFORMATION

(71) Applicant: Micron Technology, Inc., Boise, ID (US)

(72) Inventors: Yang Liu, Melissa, TX (US); Woei Chen Peh, Singapore (SG); Ruipeng Tao, Hefei (CN); Xiaoxin Zou, Singapore (SG); Tingjun Xie, Milpitas, CA (US); Aaron Lee, Sunnyvale, CA (US)

(21) Appl. No.: 19/198,864

(22) Filed: May 5, 2025

(30) Foreign Application Priority Data
Apr. 21, 2025 (WO) PCT/CN2025/090143

(51) Int. Cl. G06F 9/50

(52) U.S. Cl. CPC G06F 9/5016

(57) ABSTRACT

Methods, systems, and apparatuses include determining that a list of written wordlines for a portion of a memory device does not include wordlines belonging to a preferred wordline group. Exclusion priority information for the portion of the memory device is retrieved. The list is filtered by removing wordlines from the list that belong to the wordline groups of the exclusion priority information. A scan range is determined as aggressed wordlines in the filtered list in response to determining that the filtered list includes aggressed wordlines. A memory group scan is performed using the scan range. The portion of the memory device is allocated to a memory group using results of the memory group scan.

### CROSS-REFERENCE TO RELATED APPLICATION

The present application claims the benefit of International Application No. PCT/CN2025/090143 filed on Apr. 21, 2025, which is hereby incorporated by reference.

### TECHNICAL FIELD

The present disclosure generally relates to allocating memory groups for error avoidance, and more specifically, relates to allocating memory groups for error avoidance using priority information.

### BACKGROUND ART

A memory subsystem can include one or more memory devices that store data. The memory devices can be, for example, non-volatile memory devices and volatile memory devices. In general, a host system can utilize a memory subsystem to store data at the memory devices and to retrieve data from the memory devices.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

FIG. 1 illustrates an example computing system that includes a memory subsystem in accordance with some embodiments of the present disclosure.

FIG. 2 is a flow diagram of an example method to allocate memory groups for error avoidance using exclusion priority information in accordance with some embodiments of the present disclosure.

FIG. 3 is a flow diagram of an example method to allocate memory groups for error avoidance using inclusion priority information in accordance with some embodiments of the present disclosure.

FIG. 4 is a flow diagram of an example method to allocate memory groups for error avoidance using exclusion priority information in accordance with some embodiments of the present disclosure.

FIG. 5 is a flow diagram of an example method to allocate memory groups for error avoidance using inclusion priority information in accordance with some embodiments of the present disclosure.

FIG. 6 is a block diagram of an example computer system in which embodiments of the present disclosure may operate.

### DETAILED DESCRIPTION

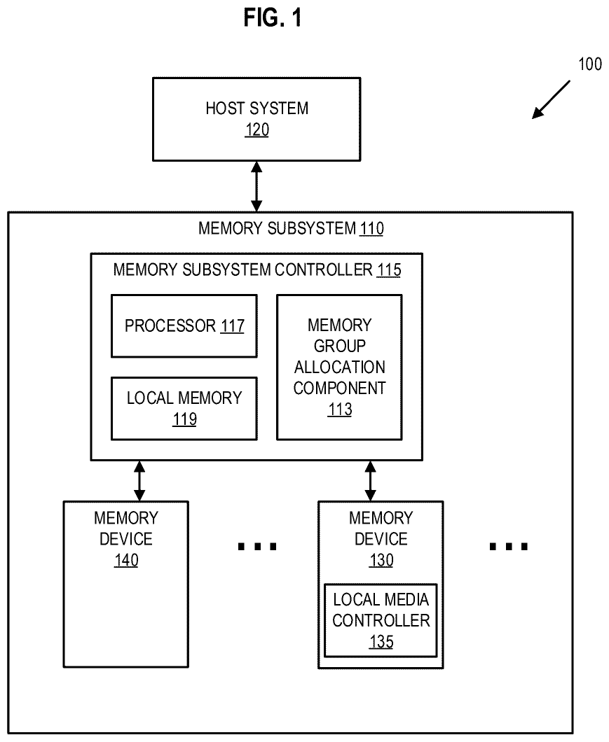

Aspects of the present disclosure are directed to allocating memory groups for error avoidance using priority information in a memory subsystem. A memory subsystem can be a storage device, a memory module, or a hybrid of a storage device and memory module. Examples of storage devices and memory modules are described below in conjunction with FIG. 1. In general, a host system can utilize a memory subsystem that includes one or more components, such as memory devices that store data. The host system can provide data to be stored at the memory subsystem and can request data to be retrieved from the memory subsystem.

A memory device can be a non-volatile memory device. A non-volatile memory device is a package of one or more dice. One example of non-volatile memory devices is a negative-and (NAND) memory device. Other examples of non-volatile memory devices are described below in conjunction with FIG. 1. The dice in the packages can be assigned to one or more channels for communicating with a memory subsystem controller. Each die can consist of one or more planes. Planes can be grouped into logic units identified by a logical unit number (LUN). For some types of non-volatile memory devices (e.g., NAND memory devices), each plane consists of a set of physical blocks, which are groups of memory cells to store data. A cell is an electronic circuit that stores information.

Depending on the cell type, a cell can store one or more bits of binary information and has various logic states that correlate to the number of bits being stored. The logic states can be represented by binary values, such as “0” and “1”, or combinations of such values. There are various types of cells, such as single-level cells (SLCs), multi-level cells (MLCs), triple-level cells (TLCs), quad-level cells (QLCs), and penta-level cells (PLCs). For example, an SLC can store one bit of information and has two logic states while a QLC can store sixteen bits of information and has sixteen logic states.

In conventional memory systems, memory devices include memory portions that have different data retention and reliability characteristics. For example, due to manufacturing defects, environment factors, and other variables, the reliability characteristics (e.g., read thresholds) for some memory portions can vary from other memory portions in the same memory device. These differences in reliability characteristics can be addressed by treating these memory portions differently. For example, memory systems can assign different read levels for different memory groups and allocate memory portions to these memory groups based on their reliability characteristics. These memory systems use memory group scans to determine the reliability characteristics for the memory portion. Because of the latency and overhead required for these scans, these conventional memory systems will limit the scan to a sample of the overall memory portion. For example, conventional systems limit reliability scans to a default wordline group to serve as a representation of an entire block. Using a scan of one of multiple wordline groups in a block as a representation of, e.g., slow charge loss in the block, is more efficient than scanning the entire block.

Variability still exists, however, within these memory portions (e.g., memory blocks). When there are no pages within the default subportion to scan (e.g., no aggressed data within the default wordline group), conventional systems select another subportion to scan. When these conventional memory systems perform a memory group scan on a memory portion, the systems can select a subportion that is not representative of the memory portion as a whole. For example, these memory systems can select wordlines (such as initial wordlines within a memory block) with significantly worse reliability characteristics than the rest of the memory portion. These conventional memory systems can therefore incorrectly allocate memory portions to memory groups with significantly worse reliability characteristics than the memory portion. Because of this incorrect allocation, applying the read level for the memory group to the memory portion results in a higher probability of errors (e.g., an increased raw bit error rate). This results in reduced performance and quality of service for the whole of the memory system due to the increased probability of errors.

Aspects of the present disclosure address the above and other deficiencies by allocating memory portions to memory groups for error avoidance using priority information for wordlines within the memory portion. For example, the memory system includes or excludes wordlines from a list of wordlines for the memory group allocation scan based on priority information for the wordlines. Accordingly, the memory system reduces the likelihood of selecting a non-representative wordline for the memory portion and therefore reduces the likelihood of incorrect memory group allocation and the associated reduction in performance and quality of service.

FIG. 1 illustrates an example computing system 100 that includes a memory subsystem 110 in accordance with some embodiments of the present disclosure. The memory subsystem 110 can include media, such as one or more volatile memory devices (e.g., memory device 140), one or more non-volatile memory devices (e.g., memory device 130), or a combination of such.

A memory subsystem 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory module (NVDIMM).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory subsystems 110. In some embodiments, the host system 120 is coupled to different types of memory subsystems 110. FIG. 1 illustrates one example of a host system 120 coupled to one memory subsystem 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processing device such as a processor chipset and a software stack executed by the processor chipset. The processor chipset can include one or more cores, one or more caches, a memory controller (e.g., NVDIMM controller), and/or a storage protocol controller (e.g., a peripheral component interconnect express (PCIe) controller, a serial advanced technology attachment (SATA) controller). The host system 120 uses the memory subsystem 110, for example, to write data to the memory subsystem 110 and read data from the memory subsystem 110.

The host system 120 can be coupled to the memory subsystem 110 via a physical host interface. Examples of a physical host interface include, but are not limited to, a SATA interface, including a mini-SATA (mSATA) interface, a PCIe interface, including a mini PCIe (mPCIE) interface, a Non-Volatile Memory Express (NVMe) interface, a universal serial bus (USB) interface, an a Fibre Channel, Serial Attached SCSI (SAS), a Small Computer System Interface (SCSI), a double data rate (DDR) memory bus, a dual in-line memory module (DIMM) interface (e.g., DIMM socket interface that supports Double Data Rate (DDR)), an Advanced Host Controller (AHCI) interface, an Open NAND Flash Interface (ONFI) interface, a Double Data Rate (DDR) interface, a Low Power Double Data Rate (LPDDR) interface, any other interface, and/or combinations of these interfaces. The physical host interface can be used to transmit data between the host system 120 and the memory subsystem 110. The host system 120 can further utilize an NVMe interface to access components (e.g., memory devices 130 and 140) when the memory subsystem 110 is coupled with the host system 120 by the PCIe interface. The physical host interface can provide an interface for passing control, address, data, and other signals between the memory subsystem 110 and the host system 120. FIG. 1 illustrates a memory subsystem 110 as an example. In general, the host system 120 can access multiple memory subsystems via the same communication connection, multiple separate communication connections, and/or a combination of communication connections.

The memory devices 130 and 140 can include any combination of the different types of non-volatile memory devices and/or volatile memory devices. The volatile memory devices (e.g., memory device 140) can be, but are not limited to, random-access memory (RAM), such as dynamic random-access memory (DRAM), synchronous dynamic random-access memory (SDRAM), video random-access memory (VRAM), and cache memory.

Some examples of non-volatile memory devices (e.g., memory device 130) include negative-and (NAND) type flash memory devices and write-in-place type memory devices, such as a three-dimensional cross-point (“3D cross-point”) memory device, which is a cross-point array of non-volatile memory cells. A cross-point array of non-volatile memory can perform bit storage based on a change of bulk resistance, in conjunction with a stackable cross-gridded data access array. Additionally, in contrast to many flash-based memories, cross-point non-volatile memory can perform a write-in-place operation, where a non-volatile memory cell can be programmed without the non-volatile memory cell being previously erased. NAND type flash memory includes, for example, two-dimensional NAND (2D NAND) and three-dimensional NAND (3D NAND).

Although non-volatile memory devices such as NAND type memory (e.g., 2D NAND, 3D NAND) and 3D cross-point array of non-volatile memory cells are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random-access memory (FeRAM), magneto random-access memory (MRAM), Spin Transfer Torque (STT)-MRAM, nano-RAM (NRAM), silicon-oxide-nitride-oxide-silicon (SONOS) memory, conductive bridging RAM (CBRAM), resistive random-access memory (RRAM), oxide based RRAM (OxRAM), negative-or (NOR) flash memory, and erasable programmable read-only memory (EPROM), including electrically erasable programmable read-only memory (EEPROM).

A memory subsystem controller 115 (or controller 115 for simplicity) can communicate with the memory devices 130 to perform operations such as reading data, writing data, or erasing data at the memory devices 130 and other such operations (e.g., in response to commands scheduled on a command bus by controller 115). The memory subsystem controller 115 can include hardware such as one or more integrated circuits and/or discrete components, a buffer memory, or a combination thereof. The hardware can include digital circuitry with dedicated (i.e., hard-coded) logic to perform the operations described herein. The buffer memory of subsystem controller 115 can include any of the volatile or non-volatile memory types mentioned above including combinations thereof. The memory subsystem controller 115 can be a microcontroller, special purpose logic circuitry (e.g., a field programmable gate array (FPGA), an application specific integrated circuit (ASIC), etc.), or another suitable processor.

The memory subsystem controller 115 can include a processing device 117 (processor) configured to execute instructions stored in memory subsystem 110 (e.g., stored in a local memory 119). In some examples, the local memory 119 of the memory subsystem controller 115 includes an embedded memory configured to store instructions for performing various processes, operations, logic flows, and routines that control operation of the memory subsystem 110, including handling communications between the memory subsystem 110 and the host system 120.

In some embodiments, the local memory 119 can include memory registers storing memory pointers, fetched data, etc. The local memory 119 can also include read-only memory (ROM) for storing micro-code. While the example memory subsystem 110 in FIG. 1 has been illustrated as including the memory subsystem controller 115, in another embodiment of the present disclosure, a memory subsystem 110 does not include a memory subsystem controller 115, and can instead rely upon external control (e.g., provided by an external host, or by a processing device or controller separate from the memory subsystem 110).

In general, the memory subsystem controller 115 can receive commands or operations from the host system 120 and can convert the commands or operations into instructions or appropriate commands to achieve the desired access to the memory devices (e.g., memory devices 130 and/or 140. The memory subsystem controller 115 can be responsible for other operations such as wear leveling operations, garbage collection operations, error detection and error-correcting code (ECC) operations, encryption operations, caching operations, and address translations between a logical address (e.g., logical block address (LBA) and/or namespace) and a physical address (e.g., physical block address) that are associated with the memory devices (e.g., memory devices 130 and/or 140). The memory subsystem controller 115 can further include host interface circuitry to communicate with the host system 120 via the physical host interface. The host interface circuitry can convert the commands received from the host system into command instructions to access the memory devices (e.g., memory devices 130 and/or 140) as well as convert responses associated with the memory devices into information for the host system 120.

The memory subsystem 110 can also include additional circuitry or components that are not illustrated. In some embodiments, the memory subsystem 110 can include a cache or buffer (e.g., DRAM) and address circuitry (e.g., a row decoder and a column decoder) that can receive an address from the memory subsystem controller 115 and decode the address to access the memory devices (e.g., memory devices 130 and/or 140).

In some embodiments, the memory devices (e.g., memory devices 130 and/or 140) include local media controllers 135 that operate in conjunction with memory subsystem controller 115 to execute operations on one or more memory cells of the memory devices (e.g., memory devices 130 and/or 140). An external controller (e.g., memory subsystem controller 115) can externally manage the memory devices (e.g., perform media management operations on the memory devices 130 and/or 140). In some embodiments, a memory device (e.g., memory device 130) is a managed memory device, which is a raw memory device combined with a local controller (e.g., local controller 135) for media management within the same memory device package. An example of a managed memory device is a managed NAND (MNAND) device.

The memory subsystem 110 includes a memory group allocation component 113 that allocates memory groups using priority information. In some embodiments, the controller 115 includes at least a portion of the memory group allocation component 113. For example, the controller 115 can include a processing device 117 configured to execute instructions stored in local memory 119 for performing the operations described herein. In some embodiments, a memory group allocation component 113 is part of the host system 120, an application, or an operating system.

The memory group allocation component 113 determines scan ranges for memory group scan operations and uses the results of the memory group scan operations to allocate portions of memory to different memory groups for error avoidance. Further details with regards to the operations of the memory group allocation component 113 are described below.

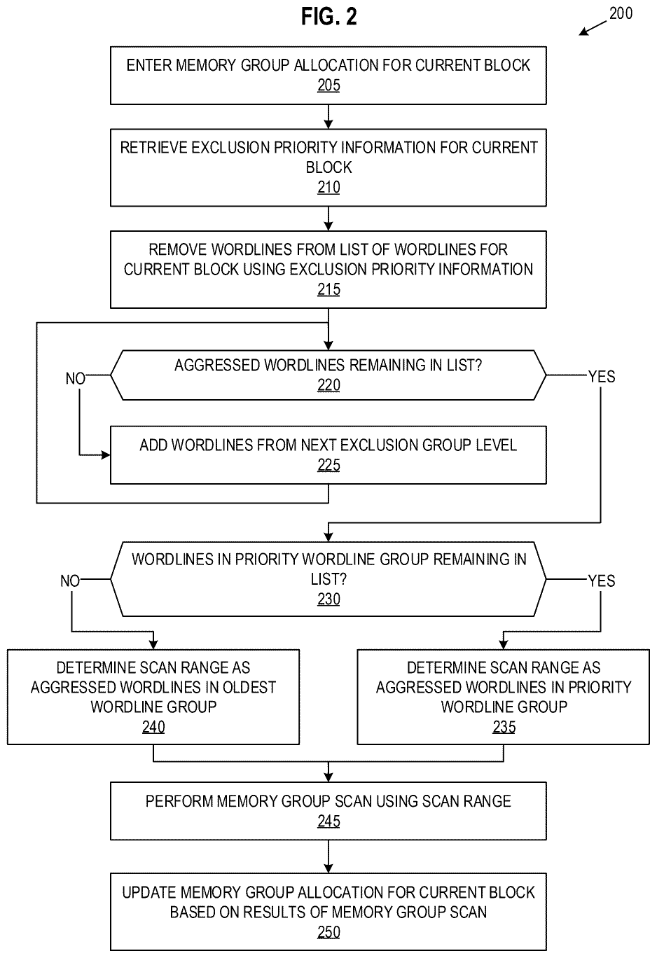

FIG. 2 is a flow diagram of an example method 200 to allocate memory groups for error avoidance using exclusion priority information, in accordance with some embodiments of the present disclosure. The method 200 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 200 is performed by the memory group allocation component 113 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 205, the processing device enters memory group allocation for the current block. For example, memory group allocation component 113 determines that the read count for a memory block of memory devices 130 is greater than a read count threshold and enters memory group allocation for that memory block. In some embodiments, memory group allocation component 113 enters memory group allocation for a memory block based on a time since a previous memory group scan. For example, memory group allocation component 113 performs memory group allocation at set time intervals.

In some embodiments, memory group allocation component 113 enters memory group allocation for a memory block based on environmental conditions for that memory block. For example, memory group allocation component 113 enters memory group allocation for a memory block in response to the temperature for the memory block satisfying a temperature threshold. In some embodiments, memory group allocation component 113 enters memory group allocation using a combination of the above methods. For example, memory group allocation component 113 enters memory group allocation for a memory block based on the historical temperatures for that memory block (and/or for the memory device a whole) and based on the read count or similar metric (e.g., program erase cycles) for that memory block.

At operation 210, the processing device retrieves exclusion priority information for the current block. For example, memory group allocation component 113 retrieves exclusion priority information for the memory block from local memory (e.g., local memory 119 of FIG. 1). In some embodiments, the exclusion priority information includes a list of wordline groups and associated exclusion priority levels. For example, the exclusion priority information includes wordline groups with associated exclusion priority levels based on how representative the wordlines are of the memory block as a whole. In such an example, wordlines that are more susceptible to voltage shift belong to wordline groups associated with higher exclusion priority levels than wordline groups for wordlines that are less susceptible to voltage shift. In some embodiments, exclusion priority information includes page ranges and associated exclusion priority levels.

In some embodiments, the processing device updates the exclusion priority information. For example, memory group allocation component 113 updates the exclusion priority information based on a portion degradation value or other determination of reliability. In some embodiments, the portion degradation value includes one or more of a read count for the memory block, previous and/or current temperatures for the memory block (and/or the memory device), and/or the runtime for the memory device. In some embodiments, the processing device updates the exclusion priority information based on read error handling statistics. For example, memory group allocation component 113 updates the exclusion priority information based on a portion degradation value for the memory block representing the change in read level (e.g., read level delta) from the base read level (e.g., default read level for memory block). In such embodiments, wordlines with more degradation (e.g., high read count, temperature, runtime, and/or read delta) are more likely to be updated to have higher exclusion priority levels than wordlines with less degradation (e.g., lower read count, temperature, runtime, and/or read delta). In some embodiments, the processing device updates the exclusion priority information in response to the portion degradation value satisfying a degradation threshold. For example, memory group allocation component 113 updates the exclusion priority information in response to the read count exceeding a threshold.

At operation 215, the processing device removes wordlines from the list of wordlines for the current block using the exclusion priority information. For example, memory group allocation component 113 removes all wordlines belonging to wordline groups listed in the exclusion priority information from a list of written wordlines for the current block.

At operation 220, the processing device determines whether there are any aggressed wordlines remaining in the list of wordlines. For example, memory group allocation component 113 determines whether any aggressed wordlines remaining in the list of written wordlines for the current memory block after the wordlines belonging to wordline groups listed in the exclusion priority information are removed. Aggressed wordlines refer to wordlines that experience significant interference from other wordlines. For example, aggressed wordlines can include wordlines that experience significant effects from disturbance due to memory operations on neighboring wordlines, wordlines that experience a higher risk of errors due to charge leakage or interference from neighboring written wordlines, and wordlines that experience unintended voltage threshold distribution shifts due to neighboring wordlines are considered aggressed wordlines. More specifically, wordlines that border other written wordlines are aggressed due to experiencing electrical interference during the programming operations for the bordering wordlines. Notably, while most wordlines experience at least some interference from other wordlines, a wordline is not considered aggressed when that inference is below a certain threshold. For example, a wordline that borders written wordlines on one side but empty wordlines on another side can be considered not aggressed as the interference experienced by such a wordline is less than that experienced by a wordline completely surrounded by other written wordlines. Accordingly, whether a wordline is aggressed can depend on considerations such as proximity to potential aggressor wordlines, the type of memory cells composing the wordline (e.g., cell density), the amount of memory operation traffic performed on nearby wordlines, and other similar factors.

In some embodiments, the processing device determines whether there are any aggressed pages in remaining in the list of written wordlines. Like aggressed wordlines, aggressed pages are pages that experience significant interference from other wordlines. Whether a page is an aggressed page involves similar considerations to those described above. Accordingly, a page that is surrounded by written pages can be considered an aggressed page while a page that is not surrounded by written pages can be considered a not aggressed page.

In some embodiments, the processing device determines whether there are any aggressed wordlines remaining using a lookup table. For example, memory group allocation component 113 retrieves a lookup table including aggressed wordlines for the current block and determines whether any of the wordlines in the list are aggressed wordlines using the lookup table. If the processing device determines that there are aggressed wordlines remaining in the list, the method 200 proceeds to operation 230. If the processing device determines that there are not aggressed wordlines remaining in the list, the method 200 proceeds to operation 225.

At operation 225, the processing device adds wordlines to the wordline list from the next lowest exclusion priority level. For example, memory group allocation component 113 adds wordlines from wordline groups associated with the lowest/next lowest exclusion priority level. As shown in FIG. 2, the processing device continues to add wordlines from the next exclusion group level to the list until there are aggressed wordlines in the list. In some embodiments, if the processing device adds wordlines from all exclusion group levels and there are still no aggressed wordlines in the list, the processing device selects scan range using random wordlines from the memory block.

At operation 230, the processing device determines whether wordlines in a priority group are remaining in the list. For example, memory group allocation component 113 determines whether the list includes any aggressed wordlines for a wordline group that is most representative of the memory block. In one embodiment, the processing device prioritizes a particular wordline group for reliability scans. Wordlines in the priority group differ from those in the list of wordlines having one or more exclusion priority levels. If the processing device determines that there are wordlines in the priority group remaining in the list, the method 200 proceeds to operation 235. If the processing device determines that there are no wordlines in the priority group remaining in the list, the method 200 proceeds to operation 240.

At operation 235, the processing device determines the scan range as aggressed wordlines in the priority wordline group. For example, memory group allocation component 113 determines the scan range as the aggressed wordlines in the list that belong to a wordline group most representative of the memory block.

At operation 240, the processing device determines the scan range as aggressed wordlines in the oldest wordline group. For example, if the processing device determines that there are no aggressed wordlines that are in the priority wordline group, the processing device instead determines a scan range as aggressed wordlines in the oldest wordline group (e.g., the wordlines that were written the most time ago). Although described as oldest wordline group, the oldest wordline group can refer to the degradation of the wordline group and not necessarily strictly the age. For example, the oldest wordline group could be the wordline group that underwent the most extreme temperatures rather than longest time of data retention.

At operation 245, the processing device performs a memory group scan using the scan range. For example, memory group allocation component 113 performs a memory group scan on the pages/wordlines in the scan range to determine the voltage drift for those pages/wordlines. In some embodiments, the processing device provides the scan range to a memory group scan component which performs a memory group scan on random pages in the scan range.

At operation 250, the processing device updates the memory group allocation for the current block based on the results of the memory group scan. For example, memory group allocation component 113 tracks the valleys of the voltage distribution for the pages in the scan range and determines how much the valleys have changed from the initial distribution. In such an example, memory group allocation component 113 assigns a memory group based on the amount of voltage drift measured by the memory group scan.

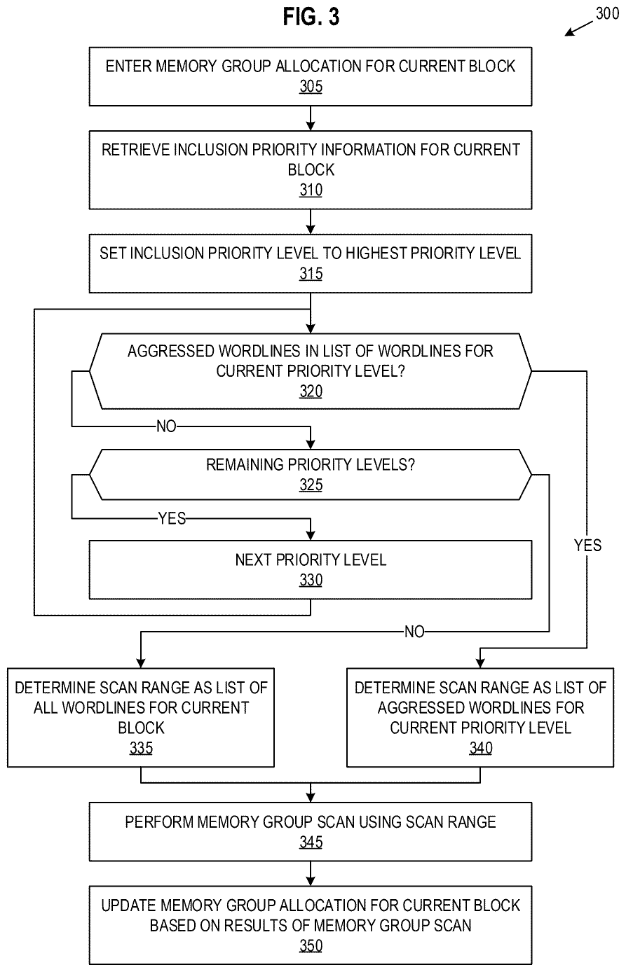

FIG. 3 is a flow diagram of an example method 300 to allocate memory groups for error avoidance using inclusion priority information, in accordance with some embodiments of the present disclosure. The method 300 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 300 is performed by the memory group allocation component 113 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 305, the processing device enters memory group allocation for the current block. For example, as described with reference to FIG. 2, memory group allocation component 113 determines that the read count for a memory block of memory devices 130 is greater than a read count threshold and enters memory group allocation for that memory block. In some embodiments, memory group allocation component 113 enters memory group allocation for a memory block based on a time since a previous memory group scan. For example, memory group allocation component 113 performs memory group allocation at set time intervals.

In some embodiments, memory group allocation component 113 enters memory group allocation for a memory block based on environmental conditions for that memory block. For example, memory group allocation component 113 enters memory group allocation for a memory block in response to the temperature for the memory block satisfying a temperature threshold. In some embodiments, memory group allocation component 113 enters memory group allocation using a combination of the above methods. For example, memory group allocation component 113 enters memory group allocation for a memory block based on the historical temperatures for that memory block (and/or for the memory device a whole) and based on the read count or similar metric (e.g., program erase cycles) for that memory block.

At operation 310, the processing device retrieves inclusion priority information for the current block. For example, memory group allocation component 113 retrieves inclusion priority information for the memory block from local memory (e.g., local memory 119 of FIG. 1). In some embodiments, the inclusion priority information includes a list of wordline groups and associated inclusion priority levels. For example, the inclusion priority information includes wordline groups with associated inclusion priority levels based on how representative the wordlines are of the memory block as a whole. In contrast with the exclusion priority information, the inclusion priority information includes wordlines that are less susceptible to voltage shift belonging to wordline groups associated with higher inclusion priority levels than wordline groups for wordlines that are more susceptible to voltage shift. Accordingly, the higher the inclusion priority level, the more representative the wordline for the memory block. In some embodiments, inclusion priority information includes page ranges and associated inclusion priority levels.

In some embodiments, the processing device updates the inclusion priority information. For example, the memory group allocation component 113 updates the inclusion priority information based on a portion degradation value or other determination of reliability. In some embodiments, the portion degradation value includes one or more of a read count for the memory block, previous and/or current temperatures for the memory block (and/or the memory device), and/or the runtime for the memory device. In some embodiments, the processing device updates the inclusion priority information based on read error handling statistics. For example, memory group allocation component 113 updates the inclusion priority information based on a portion degradation value for the memory block representing the change in read level (e.g., read level delta) from the base read level (e.g., default read level for memory block). In such embodiments, wordlines with more degradation (e.g., high read count, temperature, runtime, and/or read delta) are more likely to be updated to have lower inclusion priority levels than wordlines with less degradation (e.g., lower read count, temperature, runtime, and/or read delta). In some embodiments, the processing device updates the inclusion priority information in response to the portion degradation value satisfying a degradation threshold. For example, memory group allocation component 113 updates the inclusion priority information in response to the read count exceeding a threshold.

At operation 315, the processing device sets the inclusion priority level to the highest priority level. For example, memory group allocation component 113 includes written wordlines for the memory block that belong to the highest priority level such that the wordlines most representative for the memory block are included first.

At operation 320, the processing device determines whether there are aggressed wordlines in the list. For example, memory group allocation component 113 determines whether any aggressed wordlines are in the list of written wordlines for current inclusion priority level. In some embodiments, the processing device determines whether there are any aggressed pages in remaining in the list of written wordlines. As explained above with reference to FIG. 2, aggressed wordlines/pages refer to wordlines/pages that experience interference from other wordlines (e.g., neighboring wordlines). If the processing device determines that there are aggressed wordlines in the list of wordlines for the current priority level, the method 300 proceeds to operation 340. If the processing device determines that there are not aggressed wordlines in the list of wordlines for the current priority level, the method 300 proceeds to operation 325.

At operation 325, the processing device determines whether there are any remaining priority levels for the inclusion priority information. For example, memory group allocation component 113 determines whether there are additional lower inclusion priority levels remaining in the inclusion priority information. If the processing device determines that there are remaining priority levels in the inclusion priority information (e.g., the current priority level is not the lowest priority level), the method 300 proceeds to operation 330 and moves on to the next priority level. If the processing device determines that there are no remaining priority levels in the inclusion priority information (e.g., the current priority level is the lowest priority level), the method 300 proceeds to operation 335.

At operation 330, the processing device proceeds to the next priority level. For example, memory group allocation component 113 adds wordlines from the next highest inclusion priority level in the inclusion priority information.

At operation 335, the processing device determines the scan range as the list of all wordlines for the current block. For example, if the processing device goes through every inclusion priority level for the current block and there are no aggressed wordlines, the processing device selects the scan range as all written wordlines for the current memory block.

At operation 340, the processing device determines the scan range as list of aggressed wordlines for the current priority level. For example, if the processing device determines that there are aggressed wordlines for a certain priority level (e.g., determined at operation 320), the processing device determines a scan range as those wordlines as they are the most representative for the memory block.

At operation 345, the processing device performs a memory group scan using the scan range. For example, memory group allocation component 113 performs a memory group scan on the pages/wordlines in the scan range to determine the voltage drift for those pages/wordlines. In some embodiments, the processing device provides the scan range to a memory group scan component which performs a memory group scan on random pages in the scan range.

At operation 350, the processing device updates the memory group allocation for the current block based on the results of the memory group scan. For example, memory group allocation component 113 tracks the valleys of the voltage distribution for the pages in the scan range and determines how much the valleys have changed from the initial distribution. In such an example, memory group allocation component 113 assigns a memory group based on the amount of voltage drift measured by the memory group scan.

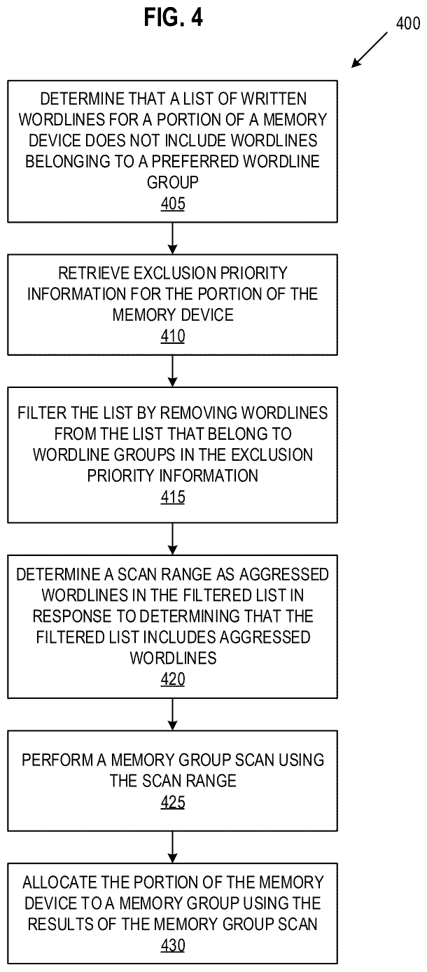

FIG. 4 is a flow diagram of an example method 400 to allocate memory groups for error avoidance using exclusion priority information, in accordance with some embodiments of the present disclosure. The method 400 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 400 is performed by the memory group allocation component 113 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 405, the processing device determines that a list of written wordlines for a portion of a memory device does not include wordlines belonging to a preferred wordline group. For example, memory group allocation component 113 determines that none of the written wordlines for a memory block belong to a wordline group most representative of the memory block.

At operation 410, the processing device retrieves exclusion priority information for the portion of the memory device. For example, memory group allocation component 113 retrieves exclusion priority information including groups of wordlines and associated priority levels from local memory (e.g., local memory 119 of FIG. 1). Further details regarding retrieving exclusion priority information for the portion of the memory device are discussed with reference to FIG. 2.

At operation 415, the processing device filters the list by removing wordlines from the list that belong to wordline groups in the exclusion priority information. For example, memory group allocation component 113 removes from the list of written wordlines for the current block any wordlines included in wordline groups in the exclusion priority information. Further details regarding filtering the list by removing wordlines from the list that belong to wordline groups in the exclusion priority information are discussed with reference to FIG. 2.

At operation 420, the processing device determines a scan range as aggressed wordlines in the filtered list in response to determining that the filtered list includes aggressed wordlines. For example, memory group allocation component 113 determines whether the list of written wordlines with the wordlines from the exclusion priority information removed includes any aggressed wordlines. In response to determining that the list does include aggressed wordlines, the processing device determines a scan range as the aggressed wordlines in that filtered list. In some embodiments, if the processing device determines that the list does not include aggressed wordlines, the processing device continues adding wordline groups from subsequent priority levels to the list until the list does include aggressed wordlines. Further details regarding determining a scan range as aggressed wordlines in the filtered list are discussed with reference to FIG. 2.

At operation 425, the processing device performs a memory group scan using the scan range. For example, memory group allocation component 113 performs a memory group scan on the pages/wordlines in the scan range to determine the voltage drift for those pages/wordlines. In some embodiments, the processing device provides the scan range to a memory group scan component which performs a memory group scan on random pages in the scan range. Further details regarding performing a memory group scan using the scan range are discussed with reference to FIG. 2.

At operation 430, the processing device allocates the portion of the memory device to a memory group using the results of the memory group scan. For example, memory group allocation component 113 tracks the valleys of the voltage distribution for the pages in the scan range and determines how much the valleys have changed from the initial distribution. In such an example, memory group allocation component 113 assigns a memory group based on the amount of voltage drift measured by the memory group scan. Further details regarding allocating the portion of the memory device to a memory group using the results of the memory group scan are discussed with reference to FIG. 2.

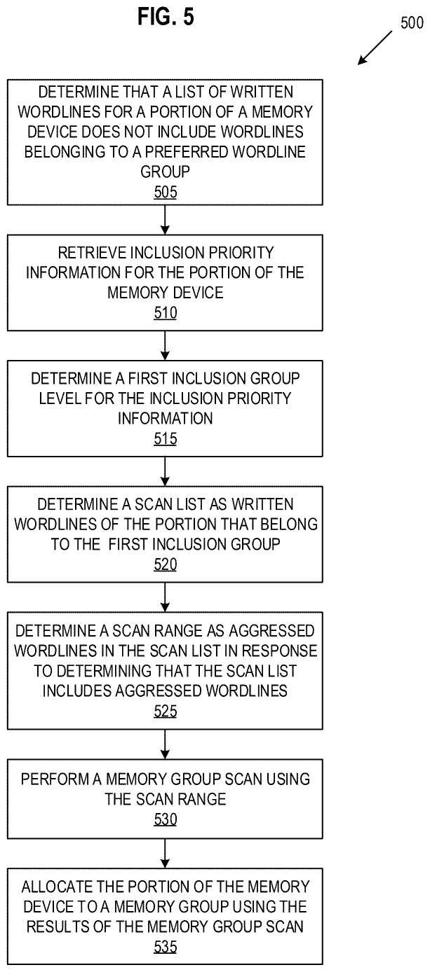

FIG. 5 is a flow diagram of an example method 500 to allocate memory groups for error avoidance using inclusion priority information, in accordance with some embodiments of the present disclosure. The method 500 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 500 is performed by the memory group allocation component 113 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 505, the processing device determines that a list of written wordlines for a portion of a memory device does not include wordlines belonging to a preferred wordline group. For example, memory group allocation component 113 determines that none of the written wordlines for a memory block belong to a wordline group most representative of the memory block.

At operation 510, the processing device retrieves inclusion priority information for a portion of the memory device. For example, memory group allocation component 113 retrieves inclusion priority information from local memory (e.g., local memory 119 of FIG. 1) for the portion of the memory device. The inclusion priority information includes wordline groups and associated inclusion group levels based on how representative the wordlines in the wordline groups are for the portion as a whole. Further details regarding retrieving inclusion priority information for a portion of the a memory device are described with reference to FIG. 3.

At operation 515, the processing device determines the first inclusion group level for the inclusion priority information. For example, memory group allocation component 113 determines a wordline group that is most representative of the memory portion. In some embodiments, memory group allocation component 113 selects the highest or the next highest inclusion priority group level. Further details regarding determining the first inclusion group level for the inclusion priority information are described with reference to FIG. 3.

At operation 520, the processing device determines a scan list as written wordlines of the portion that belong to the first inclusion group. For example, memory group allocation component 113 includes wordlines from subsequent inclusion group levels into a scan list for the memory block until there are aggressed wordlines in the scan list. Further details regarding determining a scan list as written wordlines of the portion that belong to the first inclusion group are discussed with reference to FIG. 3.

At operation 525, the processing device determines a scan range as aggressed wordlines in the scan list in response to determining that the scan list includes aggressed wordlines. For example, memory group allocation component 113 determines whether the list of wordlines from the inclusion priority information for the current inclusion group level includes any aggressed wordlines. In response to determining that the list does include aggressed wordlines, the processing device determines a scan range as the aggressed wordlines in that list. In some embodiments, if the processing device determines that the list does not include aggressed wordlines, the processing device continues adding wordline groups from subsequent priority levels to the list until the list does include aggressed wordlines. Further details regarding determining a scan range as aggressed wordlines in the scan list in response to determining that the scan list includes aggressed wordlines are discussed with reference to FIG. 3.

At operation 530, the processing device performs a memory group scan using the scan range. For example, memory group allocation component 113 performs a memory group scan on the pages/wordlines in the scan range to determine the voltage drift for those pages/wordlines. In some embodiments, the processing device provides the scan range to a memory group scan component which performs a memory group scan on random pages in the scan range. Further details regarding performing a memory group scan using the scan range are discussed with reference to FIG. 3.

At operation 535, the processing device allocates the portion of the memory device to a memory group using the results of the memory group scan. For example, memory group allocation component 113 tracks the valleys of the voltage distribution for the pages in the scan range and determines how much the valleys have changed from the initial distribution. In such an example, memory group allocation component 113 assigns a memory group based on the amount of voltage drift measured by the memory group scan. Further details regarding allocating the portion of the memory device to a memory group using the results of the memory group scan are discussed with reference to FIG. 3.

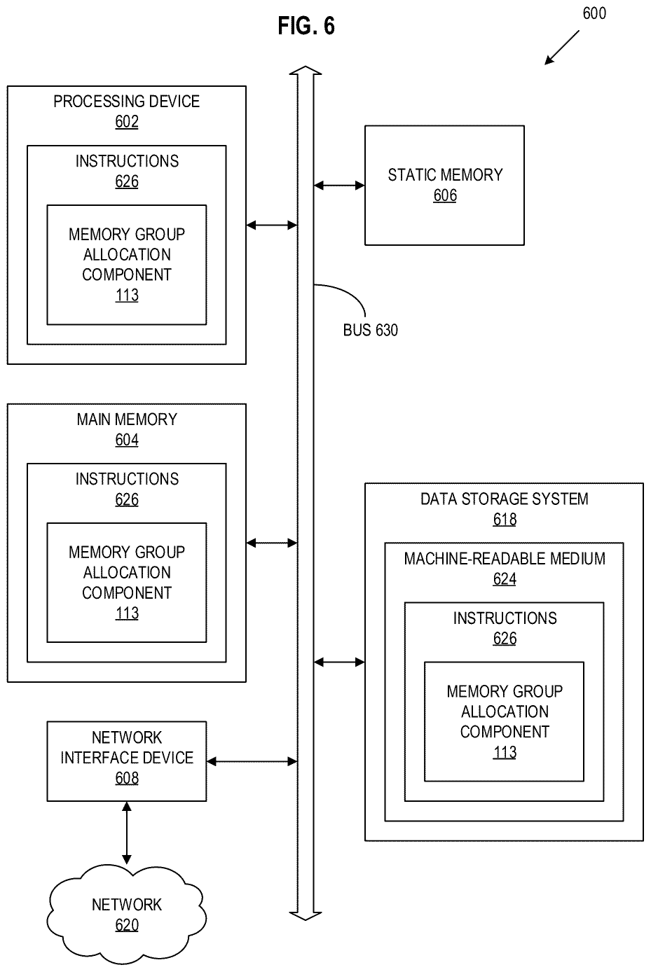

FIG. 6 illustrates an example machine of a computer system 600 within which a set of instructions for causing the machine to perform any one or more of the methodologies discussed herein can be executed. In some embodiments, the computer system 600 can correspond to a host system (e.g., the host system 120 of FIG. 1) that includes, is coupled to, or utilizes a memory subsystem (e.g., the memory subsystem 110 of FIG. 1) or can be used to perform the operations of a controller (e.g., to execute an operating system to perform operations corresponding to the memory group allocation component 113 of FIG. 1). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a smart device, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 600 includes a processing device 602, a main memory 604 (e.g., read-only memory (ROM), flash memory, dynamic random-access memory (DRAM) such as synchronous DRAM (SDRAM) or Rambus DRAM (RDRAM), etc.), a static memory 606 (e.g., flash memory, static random-access memory (SRAM), etc.), and a data storage system 618, which communicate with each other via a bus 630.

Processing device 602 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, a processor implementing other instruction sets, or processors implementing a combination of instruction sets. Processing device 602 can also be one or more special-purpose processing devices such as an application specific integrated circuit (ASIC), a field programmable gate array (FPGA), a digital signal processor (DSP), network processor, or the like. The processing device 602 is configured to execute instructions 626 for performing the operations and steps discussed herein. The computer system 600 can further include a network interface device 608 to communicate over the network 620.

The data storage system 618 can include a machine-readable storage medium 624 (also known as a computer-readable medium) on which is stored one or more sets of instructions 626 or software embodying any one or more of the methodologies or functions described herein. The instructions 626, constituting machine-readable storage media, can also reside, completely or at least partially, within the main memory 604 and/or within the processing device 602 during execution thereof by the computer system 600, the main memory 604 and the processing device 602. The machine-readable storage medium 624, data storage system 618, and/or main memory 604 can correspond to the memory subsystem 10 of FIG. 1.

In one embodiment, the instructions 626 include instructions to implement functionality corresponding to a memory group allocation component (e.g., memory group allocation component 113 of FIG. 1). While the machine-readable storage medium 624 is shown in an example embodiment to be a single medium, the term “machine-readable storage medium” should be taken to include a single medium or multiple media that store the one or more sets of instructions (e.g., instructions 626). The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general-purpose computer selectively activated or reconfigured by a computer program stored in the computer. For example, a computer system or other data processing system, such as the controller 115, may carry out the computer-implemented methods 200, 300, 400, and 500 in response to its processor executing a computer program (e.g., a sequence of instructions) contained in a memory or other non-transitory machine-readable storage medium. Such a computer program can be stored in a computer readable storage medium, such as, but not limited to, any type of disk including floppy disks, optical disks, CD-ROMs, and magnetic-optical disks, read-only memories (ROMs), random-access memories (RAMs), EPROMs, EEPROMs, magnetic or optical cards, or any type of media suitable for storing electronic instructions coupled to a computer system bus.

The algorithms and displays presented herein are not inherently related to any particular computer or other apparatus. Various general-purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A method comprising:
determining that a list of written wordlines for a portion of a memory device does not include wordlines belonging to a preferred wordline group, wherein the memory device includes a plurality of portions including the portion;
retrieving exclusion priority information for the portion of the memory device, wherein the exclusion priority information includes a plurality of wordline groups other than the preferred wordline group associated with a plurality of exclusion group levels;
filtering the list by removing wordlines from the list that belong to the plurality of wordline groups;
determining a scan range as aggressed wordlines in the filtered list in response to determining that the filtered list includes aggressed wordlines;
performing a memory group scan using the scan range; and
allocating the portion of the memory device to a memory group using results of the memory group scan.

2. The method of claim 1, further comprising:
updating the filtered list by adding wordlines to the filtered list using the exclusion priority information in response to determining that the filtered list does not include aggressed wordlines.

3. The method of claim 2, wherein updating the filtered list comprises:
determining a next exclusion group level of the plurality of exclusion group levels for the exclusion priority information; and
determining the wordlines to add to the filtered list as wordline group of the plurality of wordline groups associated with the next exclusion group level.

4. The method of claim 1, further comprising:
determining that the filtered list includes wordlines belonging to a representative wordline group, wherein determining the scan range comprises determining the scan range as aggressed wordlines belonging to the representative wordline group.

5. The method of claim 1, further comprising:
determining that the filtered list does not include wordlines belonging to a representative wordline group, wherein determining the scan range comprises determining the scan range as aggressed wordlines belonging to an oldest wordline group of aggressed wordlines in the filtered list.

6. The method of claim 1, wherein performing the memory group scan using the scan range comprises:
randomly selecting wordlines in the scan range; and
performing the memory group scan on the randomly selected wordlines.

7. The method of claim 1, further comprising:
determining a portion degradation value for the portion of the memory device; and
updating the exclusion priority information in response to the portion degradation value satisfying a degradation threshold.

8. A non-transitory computer-readable storage medium comprising instructions that, when executed by a processing device, cause the processing device to:
determine that a list of written wordlines for a portion of a memory device does not include wordlines belonging to a preferred wordline group, wherein the memory device includes a plurality of portions including the portion;
retrieve exclusion priority information for the portion of the memory device, wherein the exclusion priority information includes a plurality of wordline groups other than the preferred wordline group associated with a plurality of exclusion group levels;
filter the list by removing wordlines from the list that belong to the plurality of wordline groups;
determine a scan range as aggressed wordlines in the filtered list in response to determining that the filtered list includes aggressed wordlines;
perform a memory group scan using the scan range; and
allocate the portion of the memory device to a memory group using results of the memory group scan.

9. The non-transitory computer-readable storage medium of claim 8, wherein the processing device is further to:
update the filtered list by adding wordlines to the filtered list using the exclusion priority information in response to determining that the filtered list does not include aggressed wordlines.

10. The non-transitory computer-readable storage medium of claim 9, wherein updating the filtered list comprises:
determining a next exclusion group level of the plurality of exclusion group levels for the exclusion priority information; and
determining the wordlines to add to the filtered list as wordline group of the plurality of wordline groups associated with the next exclusion group level.

11. The non-transitory computer-readable storage medium of claim 8, wherein the processing device is further to:
determine that the filtered list includes wordlines belonging to a representative wordline group, wherein determining the scan range comprises determining the scan range as aggressed wordlines belonging to the representative wordline group.

12. The non-transitory computer-readable storage medium of claim 8, wherein the processing device is further to:
determine that the filtered list does not include wordlines belonging to a representative wordline group, wherein determining the scan range comprises determining the scan range as aggressed wordlines belonging to an oldest wordline group of aggressed wordlines in the filtered list.

13. The non-transitory computer-readable storage medium of claim 8, wherein performing the memory group scan using the scan range comprises:
randomly selecting wordlines in the scan range; and
performing the memory group scan on the randomly selected wordlines.

14. The non-transitory computer-readable storage medium of claim 8, wherein the processing device is further to:
determine a portion degradation value for the portion of the memory device; and
update the exclusion priority information in response to the portion degradation value satisfying a degradation threshold.

15. A system comprising:
a plurality of memory devices; and
a processing device, operatively coupled with the plurality of memory devices, to:
determine that a list of written wordlines for a portion of a memory device does not include wordlines belonging to a preferred wordline group, wherein the memory device includes a plurality of portions including the portion;
retrieve exclusion priority information for the portion of the memory device, wherein the exclusion priority information includes a plurality of wordline groups other than the preferred wordline group associated with a plurality of exclusion group levels;
filter the list by removing wordlines from the list that belong to the plurality of wordline groups;
update the filtered list by adding wordlines to the filtered list using the exclusion priority information in response to determining that the filtered list does not include aggressed wordlines;
determine a scan range as aggressed wordlines in the filtered list in response to determining that the filtered list includes aggressed wordlines;
perform a memory group scan using the scan range; and
allocate the portion of the memory device to a memory group using results of the memory group scan.

16. The system of claim 15, wherein updating the filtered list comprises:
determining a next exclusion group level of the plurality of exclusion group levels for the exclusion priority information; and
determining the wordlines to add to the filtered list as wordline group of the plurality of wordline groups associated with the next exclusion group level.

17. The system of claim 15, wherein the processing device is further to:
determine that the filtered list includes wordlines belonging to a representative wordline group, wherein determining the scan range comprises determining the scan range as aggressed wordlines belonging to the representative wordline group.

18. The system of claim 15, wherein the processing device is further to:
determine that the filtered list does not include wordlines belonging to a representative wordline group, wherein determining the scan range comprises determining the scan range as aggressed wordlines belonging to an oldest wordline group of aggressed wordlines in the filtered list.

19. The system of claim 15, wherein performing the memory group scan using the scan range comprises:
randomly selecting wordlines in the scan range; and
performing the memory group scan on the randomly selected wordlines.

20. The system of claim 15, wherein the processing device is further to:
determine a portion degradation value for the portion of the memory device; and
update the exclusion priority information in response to the portion degradation value satisfying a degradation threshold.
